(19) United States
(12) Patent Application Publication
(10) Pub. No.: US 2026/0231411 A1
(43) Pub. Date: Aug. 6, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Juyoung LEE, Gyeonggi-do (KR); Young Min JEONG, Gyeonggi-do (KR)

(21) Appl. No.: 19/221,538

(22) Filed: May 29, 2025

(30) Foreign Application Priority Data
Jan. 31, 2025 (KR) 10-2025-0012211

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H10B 41/27; H10B 80/00; H10W 90/00; H10W 80/312; H10W 80/327; H10W 90/792

(57) ABSTRACT

A semiconductor device includes: a gate structure including conductive layers and insulating layers that are alternately stacked; a single crystal channel layer; and a source layer. The single crystal channel layer includes a penetration portion extending through the gate structure and an expansion portion protruding from the gate structure and having a greater width than the penetration portion at a portion where the penetration portion and the expansion portion are connected. The source layer is located above the gate structure and surrounds the expansion portion.

### CROSS-REFERENCE TO RELATED APPLICATION

This application claims priority under 35 U.S.C. § 119 to Korean Patent Application No. 10-2025-0012211 filed on Jan. 31, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

The degree of integration of a semiconductor device is mainly determined by an area occupied by a unit memory cell. Recently, as improvement in the degree of integration of a semiconductor device for forming memory cells in a single layer on a substrate approaches a limit, proposals have been made for a three-dimensional semiconductor device for stacking memory cells on a substrate. Additionally, to improve the operational reliability of such semiconductor devices, various structures and manufacturing methods have been developed.

### SUMMARY

Embodiments of the present disclosure are directed to providing a semiconductor device with a high degree, a stable structure, and improved reliability.

In an embodiment, a semiconductor device may include: a gate structure including conductive layers and insulating layers that are alternately stacked; a single crystal channel layer; and a source layer. The single crystal channel layer includes a penetration portion extending through the gate structure and an expansion portion protruding from the gate structure and having a greater width than the penetration portion at a portion where the penetration portion and the expansion portion are connected. The source layer is located above the gate structure and surrounds the expansion portion.

In an embodiment, a method of manufacturing a semiconductor device may include: forming a first opening in a substrate; forming a stack on the substrate; forming a second opening extending through the stack and connected to the first opening; forming a single crystal channel layer in the first opening and the second opening; etching the substrate; and forming a source layer by doping the etched substrate with impurities.

In an embodiment, a method of manufacturing a semiconductor device may include: forming a first wafer including a substrate, a stack formed on the substrate, and a single crystal channel layer extending into the substrate through the stack; forming a second wafer including a peripheral circuit; bonding the first wafer and the second wafer to each other; etching the substrate; and forming a source layer by doping the etched substrate with impurities.

### BRIEF DESCRIPTION OF THE DRAWINGS

FIGS. 1A and 1B are cross-sectional views illustrating the structure of a semiconductor device in accordance with an embodiment of the present disclosure.

FIG. 2 is a diagram illustrating the structure of a semiconductor device in accordance with an embodiment of the present disclosure.

FIGS. 3A to 3H are diagrams for describing a method of manufacturing a semiconductor device in accordance with an embodiment of the present disclosure.

FIGS. 4A and 4B are diagrams for describing a method of manufacturing a semiconductor device in accordance with an embodiment of the present disclosure.

FIGS. 5A to 5D are diagrams for describing a method of manufacturing a semiconductor device in accordance with an embodiment of the present disclosure.

FIG. 6 is a configuration diagram of a semiconductor device in accordance with an embodiment of the present disclosure.

FIG. 7 is a configuration diagram of a semiconductor device in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and scope of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the principles and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

An embodiment of the present disclosure provides a semiconductor device having a stable structure and improved characteristics and a method of manufacturing the semiconductor device.

By stacking memory cells in three dimensions as described in the present disclosure, the embodiments disclosed herein improve the degree of integration of a semiconductor device. The embodiments provide a semiconductor device having a stable structure and improved reliability.

Hereafter, embodiments in accordance with the technical concept of the present disclosure will be described with reference to the accompanying drawings.

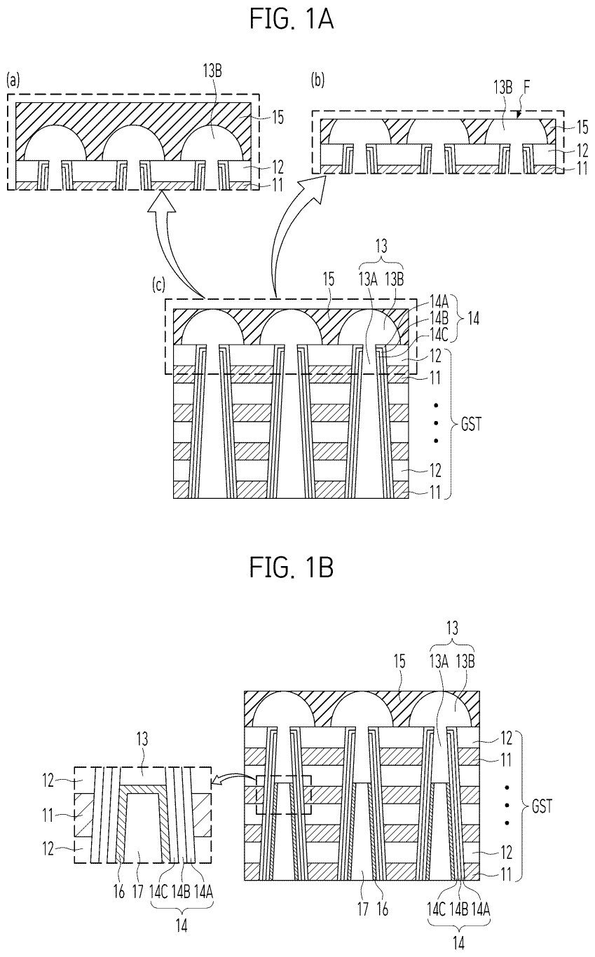

FIGS. 1A and 1B are cross-sectional views illustrating the structure of a semiconductor device in accordance with an embodiment.

Referring to FIG. 1A, the semiconductor device may include a gate structure GST, a single crystal channel layer 13, a source layer 15, and a memory layer 14. The gate structure GST may include conductive layers 11 and insulating layers 12 that are alternately stacked. The conductive layers 11 may be gate lines such as a source select line, word lines, or a drain select line. The conductive layers 11 may each include a conductive material such as polysilicon, tungsten, or molybdenum. The insulating layers 12 may be used to insulate the stacked conductive layers 11 from each other. The insulating layers 12 may each include oxide, nitride, air gap, or the like.

The single crystal channel layer 13 may extend into the source layer 15 through the gate structure GST. The single crystal channel layer 13 may include a penetration portion 13A and an expansion portion 13B connected to the penetration portion 13A. The penetration portion 13A may extend through the gate structure GST, and may have a cross section with a tapered shape (or a bowing shape in which the width of the middle level is greater than the top and bottom widths. At a portion where the penetration portion 13A and the expansion portion 13B are connected to each other, the expansion portion 13B may have a greater width than the penetration portion 13A. The expansion portion 13B may protrude from an upper surface of the gate structure GST. The expansion portion 13B may be in contact with the upper surface of the gate structure GST, and may include a curved surface protruding from the upper surface of the gate structure GST. As an example, the expansion portion 13B may have a hemispherical shape (or otherwise semi-elliptical shape), and may have a uniform single crystal structure.

The penetration portion 13A and the expansion portion 13B may have substantially the same doping concentration or have different doping concentrations. As an example, a doping concentration of the expansion portion 13B may be greater than a doping concentration of the penetration portion 13A. In this instance, the penetration portion 13A may be implemented as a channel layer, and the expansion portion 13B may be implemented as a source layer.

The memory layer 14 may include at least one of a blocking layer 14A, a data storage layer 14B, and a tunneling layer 14C. The memory layer 14 may partially surround the single crystal channel layer 13 (for example, enclose a portion of the single crystal channel layer 13). As an example, the memory layer 14 may surround a sidewall of the penetration portion 13A of the single crystal channel layer 13, and might not surround the expansion portion 13B of the single crystal channel layer 13.

Source select transistors, memory cells, or drain select transistors may be located in regions where the single crystal channel layer 13 and the conductive layers 11 intersect with each other. At least one drain select transistor, a plurality of memory cells, and at least one source select transistor that are sequentially stacked may constitute one memory string, and may share the single crystal channel layer 13 with each other. As an example, the source select transistor, the memory cell, and the drain select transistor may use a single crystal silicon layer as a channel layer. By forming the single crystal channel layer 13 instead of a polycrystalline channel layer, the embodiment as disclosed may improve a cell current.

The source layer 15 may be located on the gate structure GST, and may surround the expansion portion 13B. The source layer 15 may be filled between adjacent expansion portions 13B. As an example, the source layer 15 may be a substrate doped with impurities.

Referring to (c) of FIG. 1A, an upper surface of the source layer 15 may be located at substantially the same level as an upper surface of the single crystal channel layer 13. However, a height of the source layer 15 is not limited thereto. Referring to (a) of FIG. 1A, an upper surface of the source layer 15 may be located at a higher level than an upper surface of the single crystal channel layer 13. An entire surface of the expansion portion 13B may be surrounded by the source layer 15. Referring to (b) of FIG. 1A, the single crystal channel layer 13 may have a flat upper surface F. The upper surface of the source layer 15 and the flat upper surface of the single crystal channel layer 13 may be located at substantially the same level.

Referring to FIG. 1B, the semiconductor device may include a gate structure GST, a single crystal channel layer 13, a polycrystalline channel layer 16, and a source layer 15. The semiconductor device may further include a memory layer 14 and an insulating core 17. The gate structure GST may include conductive layers 11 and insulating layers 12 that are alternately stacked. The single crystal channel layer 13 may extend into the source layer 15 through the gate structure GST. The source layer 15 may be located on the gate structure GST, and may surround an expansion portion 13B.

The single crystal channel layer 13 may include a penetration portion 13A extending through the gate structure GST and an expansion portion 13B protruding into the source layer 15. The polycrystalline channel layer 16 may extend through the gate structure GST, and may be connected to the single crystal channel layer 13. The polycrystalline channel layer 16 and the penetration portion 13A may be connected to each other. The memory layer 14 may surround the penetration portion 13A of the single crystal channel layer 13 and the polycrystalline channel layer 16. The insulating core 17 may be located in the polycrystalline channel layer 16. As an example, the polycrystalline channel layer 16 may surround a sidewall of the insulating core 17, and the insulating core 17 and the single crystal channel layer 13 may be in contact with each other. Alternatively, the polycrystalline channel layer 16 may be located between the single crystal channel layer 13 and the insulating core 17, and may have a cross section with a (for example, inverted, as shown in FIG. 1B) U shape. The polycrystalline channel layer 16 may include polysilicon, and the insulating core 17 may include oxide, nitride, air gap, or the like.

At least one drain select transistor, a plurality of memory cells, and at least one source select transistor may be stacked along the polycrystalline channel layer 16 and the single crystal channel layer 13 which are interconnected. The at least one drain select transistor, the plurality of memory cells, and the at least one source select transistor may constitute one memory string. Each of the at least one drain select transistor, the memory cells, and the at least one source select transistor included in one memory string may include the single crystal channel layer 13 or the polycrystalline channel layer 16. According to an embodiment, the source select transistor may include the single crystal channel layer 13, and the plurality of memory cells and the drain select transistor may include the polycrystalline channel layer 16. According to another embodiment, the source select transistor and at least one memory cell (of the plurality of memory cells) adjacent to the source select transistor may include the single crystal channel layer 13, and the remaining memory cells (of the plurality of memory cells) and the drain select transistor may include the polycrystalline channel layer 16. Based on the structure of this embodiment, the transistors included in one memory string may include different types of channel layers. A cell current may be improved by the source select transistor including the single crystal channel layer 13, and a cell distribution may be improved by the memory cell and the drain select transistor including the polycrystalline channel layer 16.

According to the structure described above, at least one of the source select transistor, the memory cell, and the drain select transistor may include the single crystal channel layer 13. Accordingly, the cell current of the semiconductor device may be improved, and a memory window may be secured.

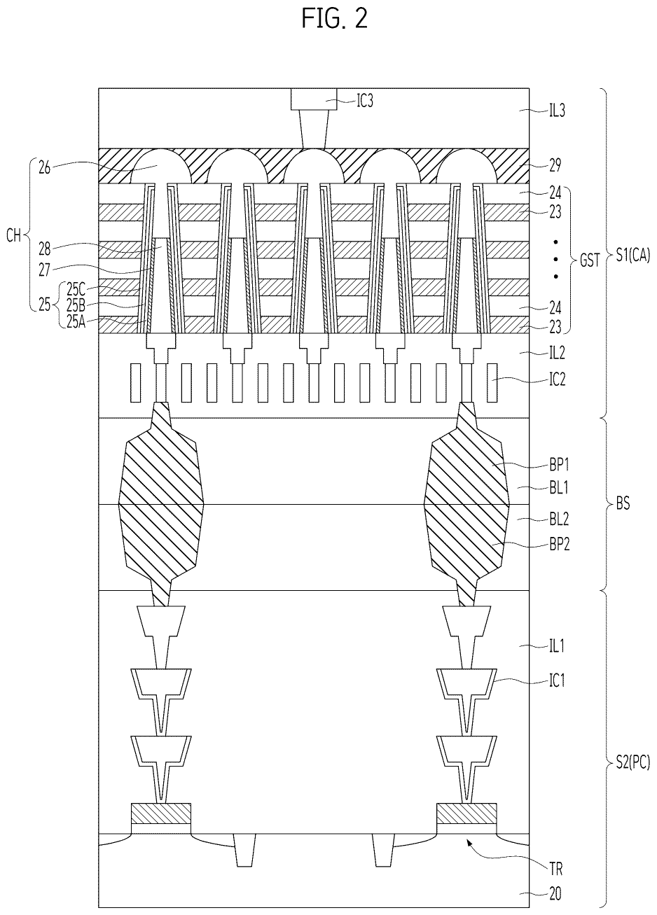

FIG. 2 is a diagram illustrating the structure of a semiconductor device in accordance with an embodiment. Hereinafter, content overlapping with the previously described content may be omitted.

Referring to FIG. 2, the semiconductor device may include a first semiconductor structure S1, a second semiconductor structure S2, and a bonding structure BS. In some embodiments, the first semiconductor structure S1 may include a memory cell array CA, and the second semiconductor structure S2 may include a peripheral circuit PC.

The first semiconductor structure S1 may include a gate structure GST, a channel structure CH, a source layer 29, a second interlayer insulating layer IL2, a second interconnection structure IC2, a third interlayer insulating layer IL3, and a third interconnection structure IC3. The gate structure GST may include conductive layers 23 and insulating layers 24 that are alternately stacked.

The source layer 29 may be located above the gate structure GST, and the second interlayer insulating layer IL2 may be located below the gate structure GST. The third interlayer insulating layer IL3 may be located above the source layer 29. The second interconnection structure IC2 may be located in the second interlayer insulating layer IL2. The second interconnection structure IC2 may include a bit line, and the bit line may be connected to a polycrystalline channel layer 27. The third interconnection structure IC3 may be located in the third interlayer insulating layer IL3, and may be electrically connected to the source layer 29.

The channel structure CH may be connected between the source layer 29 and the bit line. The channel structure CH may include a single crystal channel layer 26 or include a single crystal channel layer 26 and a polycrystalline channel layer 27. The channel structure CH may further include at least one of an insulating core 28 and a memory layer 25. The memory layer 25 may include at least one of a blocking layer 25A, a data storage layer 25B, and a tunneling layer 25C.

The second semiconductor structure S2 may include a substrate 20, a transistor TR, a first interlayer insulating layer IL1, and a first interconnection structure IC1. The transistor TR may belong to (for example, be included in) the peripheral circuit PC. As an example, the peripheral circuit PC may include a page buffer, a row decoder, a logic circuit, an input and output (input/output) circuit, and the like. The first interconnection structure IC1 may be located in the first interlayer insulating layer IL1, and may be electrically connected to the peripheral circuit PC.

The bonding structure BS may be located between the first semiconductor structure S1 and the second semiconductor structure S2, and may bond the first semiconductor structure S1 and the second semiconductor structure S2 to each other. The bonding structure BS may include a first bonding layer BL1, a second bonding layer BL2, a first bonding pad BP1, and a second bonding pad BP2.

The peripheral circuit PC and the memory cell array CA may be physically bonded to each other by the first bonding layer BL1 and the second bonding layer BL2. The first bonding layer BL1 and the second bonding layer BL2 may each include silicon caron nitride (SiCN), tetra ethyl ortho silicate (TEOS), or the like. The first bonding pad BP1 and the second bonding pad BP2 may be electrically connected to each other at an interface between the first bonding layer BL1 and the second bonding layer BL2. The first bonding pad BP1 may be electrically connected to the memory cell array CA through the second interconnection structure IC2. The second bonding pads BP2 may be electrically connected to the peripheral circuit PC through the first interconnection structure IC1. Accordingly, the peripheral circuit PC and the memory cell array CA may be electrically connected to each other through the first bonding pad BP1 and the second bonding pad BP2.

According to the structure described above, the first semiconductor structure S1 and the second semiconductor structure S2 formed using separate manufacturing processes may be electrically connected to each other through the bonding structure BS. The first semiconductor structure S1 may include the memory cell array CA, and each memory string of the memory cell array CA may include the single crystal channel layer 26 or include the single crystal channel layer 26 and the polycrystalline channel layer 27.

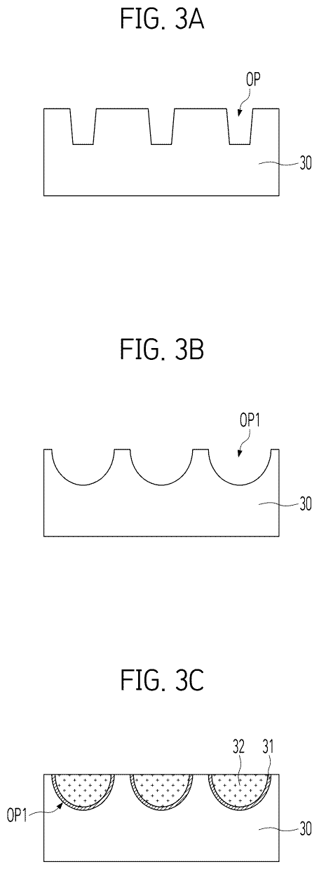

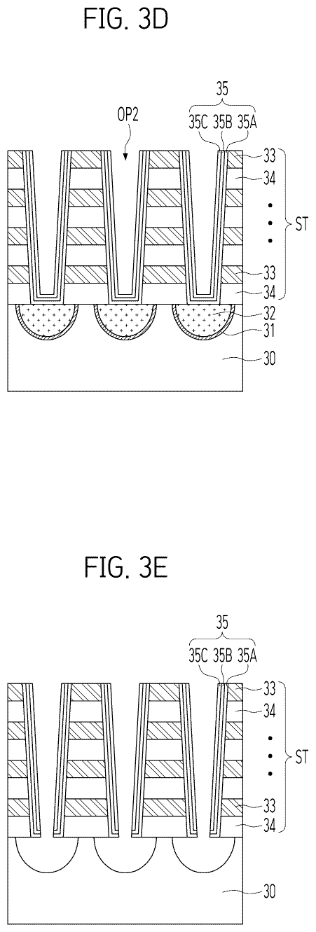

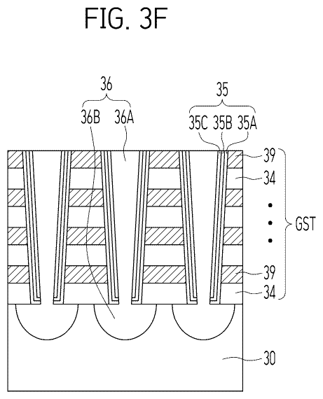

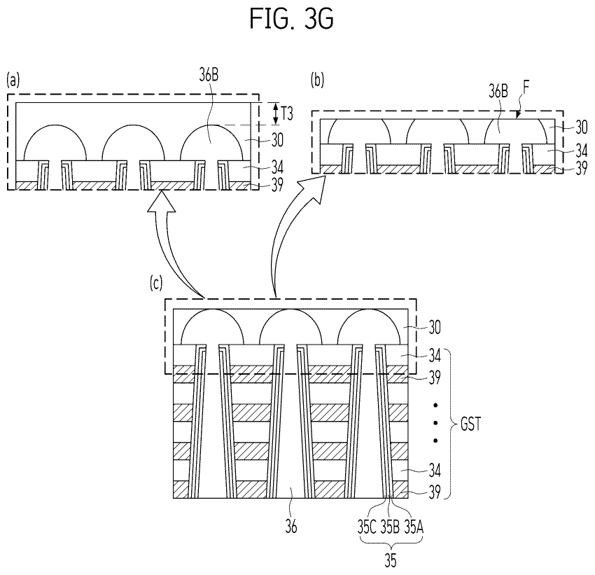

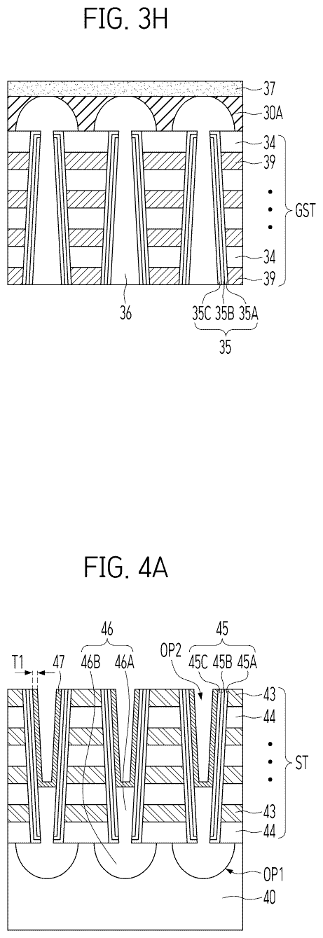

FIGS. 3A to 3H are diagrams for describing a method of manufacturing a semiconductor device in accordance with the embodiments of the present disclosure. Hereinafter, the content overlapping with the previously described content may be omitted.

Referring to FIGS. 3A and 3B, a first opening OP1 may be formed in a substrate 30. First, referring to FIG. 3A, an initial opening OP may be formed in the substrate 30. The initial opening OP may be formed using a shallow trench isolation (STI) process of forming an element isolation trench. As an example, a plurality of initial openings OP arranged in a first direction I and a second direction II intersecting the first direction I may be formed. The initial openings OP may be arranged at sufficient intervals in consideration of a prospective width to be expanded in a subsequent process. Subsequently, referring to FIG. 3B, the first opening OP1 may be formed by expanding the initial opening OP. As an example, the substrate 30 may be etched using an isotropic etching process such as a wet etching process. Through this etching process, the initial opening OP may be expanded in a hemispherical, or ovoid (or other semi-elliptical cross sectional) shape.

Referring to FIG. 3C, a curing process may be performed. The curing process may be a process for treating a surface of the substrate 30 exposed by the first opening OP1. As an example, the curing process may include at least one of a cleaning process, an implant process, and an annealing process. Alternatively, in additional embodiments, the curing process may be performed on the surface of the substrate 30 exposed through the opening OP without expanding the opening OP.

Initially, in the cleaning process, chemicals, etching byproducts, or the like, existing on an inner surface of the first opening OP1 may be removed by performing the cleaning process. The cleaning process may be performed using deionized water. NH₃, H₂O₂, citric acid, and the like, may be added to the deionized water.

Subsequently, a doping concentration of a single crystal channel layer may be adjusted by performing an implant process. As an example, P-type impurities such as boron (B), aluminum (Al), and gallium (Ga) may be doped or N-type impurities such as phosphorus (P), arsenic (As), and antimony (Sb) may be doped. A doping concentration of the impurities may be determined in consideration of a threshold voltage of a source select transistor.

Subsequently, the annealing process may be performed. The doped impurities may be activated by the annealing process. In addition, damage existing on the surface of the substrate 30 may be cured, and a protective layer 31 may be formed. The protective layer 31 may be used to protect the surface of the substrate 30 from chemicals used to deposit an etch-stop layer 32 or deposition byproducts in a subsequent process. As an example, the protective layer 31 may be an oxide layer.

By performing the curing process as described above, the embodiments provide the capability to remove the chemicals, the byproducts, or the like, from the surface of the substrate 30. When the first opening OP1 has a hemispherical shape, the surface of the substrate 30 includes a curved surface, and thus, the chemicals, the byproducts, or the like, may be effectively removed in the curing process.

Subsequently, an etch-stop layer 32 may be formed in the first opening OP1. The etch-stop layer 32 may include a material having a high etching selectivity with respect to material layers formed in a subsequent process, e.g., first material layers 33 and second material layers 34 formed in a process of FIG. 3D. As an example, the etch-stop layer 32 may include carbon.

Referring to FIG. 3D, a stack ST may be formed on the substrate 30. The stack ST may include first material layers 33 and second material layers 34 that are alternately stacked. In the illustrated example of stack ST, one second material layer 34 is formed on the substrate 30, and one first material layer 33 is then formed on the one second material layer 34. The first material layers 33 may each include a material having a high etching selectivity with respect to the second material layers 34. The first material layers 33 are used to form gate lines, and may each include a sacrificial material such as nitride or a conductive material such as polysilicon or metal. The second material layers 34 are used to insulate the stacked gate lines from each other, and may each include an insulating material such as oxide or nitride.

Subsequently, a second opening OP2 may be formed in the stack ST. As an example, the second opening OP2 extending through the stack ST may be formed by etching the stack ST using the etch-stop layer 32. The etch-stop layer 32 may be exposed through the second opening OP2. A plurality of first openings OP1 and a plurality of second openings OP2 may be connected to each other, respectively. The second opening OP2 may have a cross section with a tapered shape or a bowing shape. At a portion where the first opening OP1 and the second opening OP2 are connected to each other, the second opening OP2 may have a smaller width than the first opening OP1.

Subsequently, a memory layer 35 may be formed in the second opening OP2. The memory layer 35 may be conformally formed along an inner surface of the second opening OP2. As an example, a blocking layer 35A may be formed along a surface of the stack ST and a surface of the etch-stop layer 32, a data storage layer 35B may be formed on the blocking layer 35A, and a tunneling layer 35C may be formed on the data storage layer 35B. The data storage layer 35B may include a floating gate, polysilicon, a charge trap material, nitride, a variable resistance material, or the like.

Referring to FIG. 3E, the etch-stop layer 32 may be exposed by etching the memory layer 35. A portion of the memory layer 35 formed on the surface of the etch-stop layer 32 may be etched, and the memory layer 35 may remain on an inner wall of the second opening OP2.

Subsequently, the etch-stop layer 32 may be removed. As an example, the etch-stop layer 32 may be selectively etched, and through this, the protective layer 31 may be exposed. Subsequently, the protective layer 31 may be removed. As an example, the substrate 30 may be exposed by etching the protective layer 31. After the protective layer 31 is removed, unnecessary materials existing on the surface of the substrate 30 may be removed by performing a cleaning process. In addition, the substrate 30 may be surface-treated. As an example, oxygen atoms existing on the surface of the substrate 30 may be removed by surface-treating the substrate 30 by a method such as plasma activation, liquid activation, or the like.

Referring to FIG. 3F, a single crystal channel layer 36 may be formed in the first opening OP1 and the second opening OP2. As an example, the single crystal channel layer 36 may be formed by growing single crystal silicon from the substrate 30 using an epitaxial growth method. The single crystal channel layer 36 may include an expansion portion 36B in the first opening OP1 and a penetration portion 36A in the second opening OP2. The expansion portion 36B may be grown using the substrate 30 as a seed. Because the first opening OP1 has the hemispherical shape, the expansion portion 36B may be grown in a uniform single crystal structure. In addition, the penetration portion 36A may be grown using the expansion portion 36B as a seed.

The expansion portion 36B may have a shape transferred from the first opening OP1, which may be a hemispherical shape. The penetration portion 36A may have a shape transferred from the second opening OP2, which may be a pillar shape. According to an alternate embodiment, when the initial opening OP is not expanded, single crystal silicon may be grown from the substrate 30 exposed through the opening OP, and the expansion portion may have a shape transferred from the opening OP.

Because single crystal silicon is grown in a state where the surface of the substrate 30 is optimized by the curing process, the cleaning process, the surface treatment process, and the like, the single crystal silicon may be uniformly grown from the substrate 30. In addition, the single crystal silicon may be grown without a void in the first and second openings OP1 and OP2.

Subsequently, the first material layers 33 may be replaced with third material layers 39. As an example, a slit extending through the stack ST may be formed, and the first material layers 33 may be removed through the slit. Subsequently, the third material layers 39 may be formed in regions where the first material layers 33 are removed. The third material layers 39 may be used to form gate lines, and may each include metal such as tungsten or molybdenum. Through this, a gate structure GST including the second material layers 34 and the third material layers 39 that are alternately stacked may be formed.

According to an alternate embodiment, when the first material layers 33 each include a conductive material, a process of replacing the first material layers 33 with the third material layers 39 may be omitted. In these instances, the first material layers 33 may be used as the gate lines, and the stack ST may be used as the gate structure GST.

Referring to FIG. 3G, the substrate 30 may be etched. As an example, the substrate 30 may be etched after a wafer is turned over so that the substrate 30 is located above the gate structure GST. The substrate 30 may be polished using a planarization process, and a chemical mechanical polish (CMP) method may be used in the planarization process.

A level of an upper surface of the etched substrate 30 may be adjusted depending on a degree to which the substrate 30 is polished. Referring to (c) of FIG. 3G, the upper surface of the etched substrate 30 and a top of the single crystal channel layer 36 may be located at substantially the same level. However, the present disclosure is not limited thereto, and a planarization level of the substrate 30 may be variously adjusted. Referring to (a) of FIG. 3G, an upper surface of the substrate 30 may be located at a higher level than a top of the single crystal channel layer 36. The substrate 30 may have a third thickness T3 on the upper surface of the single crystal channel layer 36. Referring to (b) of FIG. 3G, the single crystal channel layer 36 may be etched together in a process of etching the substrate 30. The expansion portion 36B may be partially etched, and the single crystal channel layer 36 may have a flat upper surface F. The flat upper surface of the single crystal channel layer 36 may be exposed through the upper surface of the substrate 30.

Referring to FIG. 3H, a buffer layer 37 may be formed on the substrate 30. As an example, the buffer layer 37 may be formed by oxidizing the surface of the substrate 30 using an oxidation process. The buffer layer 37 may be an oxide layer.

Subsequently, a source layer 30A may be formed by doping the substrate 30 with impurities through the buffer layer 37. As an example, the substrate 30 may be doped with N-type impurities or P-type impurities. Because the impurities are doped through the buffer layer 37, the embodiments disclosed herein may prevent or reduce damage to the surface of the substrate 30 in an impurity doping process. Alternatively, in the impurity doping process, the expansion portion 36B as well as the substrate 30 may be doped with impurities. The expansion portion 36B doped with the impurities may be used as a source layer.

Subsequently, the doped impurities may be activated by performing an annealing process. Subsequently, the buffer layer 37 may be removed. As an example, the source layer 30A may be exposed by selectively etching the buffer layer 37. Because the buffer layer 37 may be damaged in the impurity doping process described above, an interlayer insulating layer may be formed after the damaged buffer layer 37 is removed.

According to the method described above, before the stack ST is formed, the opening OP and/or the first opening OP1 may be formed, and the curing process may be performed. Accordingly, the surface of the substrate 30 may be optimized as a seed for growing the single crystal silicon, and the optimized surface may be protected by the etch-stop layer 32. Because the single crystal channel layer 36 is formed from the optimized surface of the substrate 30, the single crystal channel layer 36 may be formed without a void. In addition, because the source layer 30A is formed by doping the remaining substrate 30 with the impurities, there is no need to completely remove the substrate 30, and there is no need to additionally deposit a conductive layer in order to form the source layer 30A.

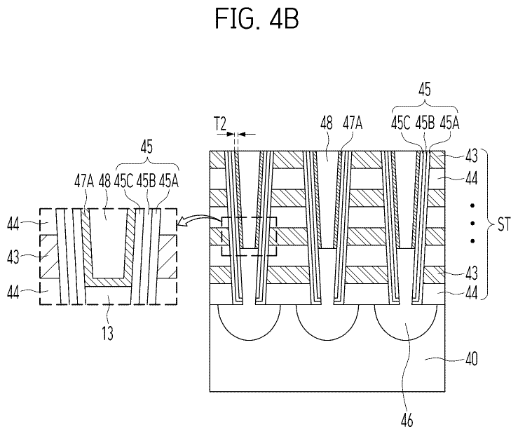

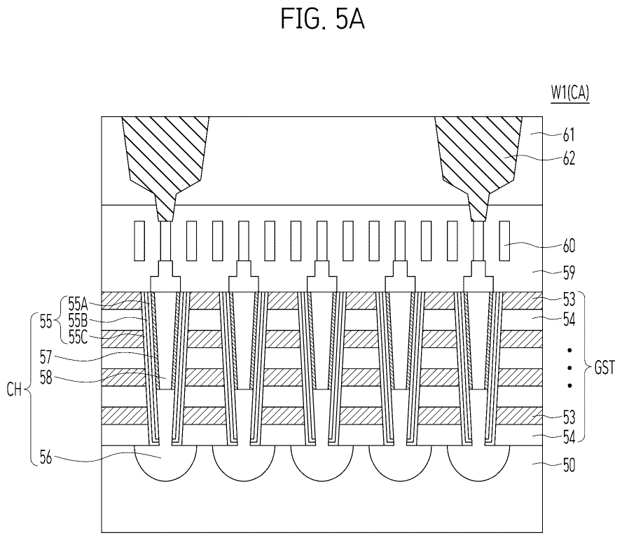

FIGS. 4A and 4B are diagrams for describing a method of manufacturing a semiconductor device in accordance with an embodiment. Hereinafter, the content overlapping with the previously described content may be omitted.

Referring to FIG. 4A, a first opening OP1 may be formed in a substrate 40, and a stack ST may be formed on the substrate 40. The stack ST may include first material layers 43 and second material layers 44 that are alternately stacked. In the illustrated example of stack ST, one second material layer 44 is formed on the substrate 40, and one first material layer 43 is then formed on the one second material layer 44. Subsequently, a second opening OP2 extending through the stack ST and connected to the first opening OP1 may be formed. Subsequently, a memory layer 45 may be formed on an inner wall of the second opening OP2. The memory layer 45 may include at least one of a blocking layer 45A, a data storage layer 45B, and a tunneling layer 45C.

Subsequently, a single crystal channel layer 46 may be formed in the first and second openings OP1 and OP2. The single crystal channel layer 46 may completely fill the first opening OP1, and may partially fill the second opening OP2. As an example, the single crystal channel layer 46 only partially filling the second opening OP2 may be formed by adjusting a growth time of single crystal silicon. The single crystal channel layer 46 may include an expansion portion 46B or include an expansion portion 46B and a penetration portion 46A.

Subsequently, a polycrystalline layer 47 may be formed in the second opening OP2. The polycrystalline layer 47 may be conformally formed along an inner surface of the second opening OP2. As an example, the polycrystalline layer 47 may be deposited along a surface of the memory layer 45 and a surface of the single crystal channel layer 46. The polycrystalline layer 47 may have a cross section with a U shape. As an example, the polycrystalline layer 47 may be formed by forming a polysilicon layer in the second opening OP2 and performing an annealing process. The polycrystalline layer 47 may be a polysilicon layer with a first thickness T1.

Referring to FIG. 4B, a polycrystalline channel layer 47A may be formed by etching the polycrystalline layer 47. Subsequently, an insulating core 48 may be formed in the polycrystalline channel layer 47A. The polycrystalline channel layer 47A may have a second thickness T2 less than the first thickness T1. By reducing a thickness of the polycrystalline channel layer 47A to the second thickness T2, the embodiments disclosed herein may improve a cell current. In a process of etching the polycrystalline layer 47, a portion of the polycrystalline layer 47 formed on the surface of the single crystal channel layer 46 may be completely removed, and the polycrystalline channel layer 47A may be formed in a spacer shape on the inner wall of the second opening OP2. In a process of etching the polycrystalline layer 47, a portion of the polycrystalline layer 47 formed on the surface of the single crystal channel layer 46 may be partially removed, and the polycrystalline channel layer 47A having a cross section with a U shape may be formed.

Subsequently, although not illustrated in FIG. 4B, the substrate 40 may be etched, and a source layer may be formed by doping the remaining substrate 40 with impurities.

According to the method described above, the single crystal channel layer 46 and the polycrystalline channel layer 47A may be formed in the second opening OP2. Because the polycrystalline channel layer 47A is formed after a lower portion of the second opening OP2 is filled with the single crystal channel layer 46, an aspect ratio of the second opening OP2 where the polycrystalline channel layer 47A is formed may be reduced, and the difficulty of an etching process for reducing the thickness of the polycrystalline channel layer 47A may be reduced.

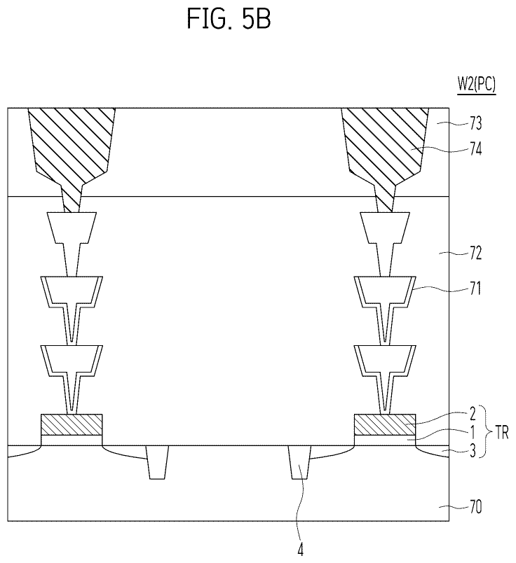

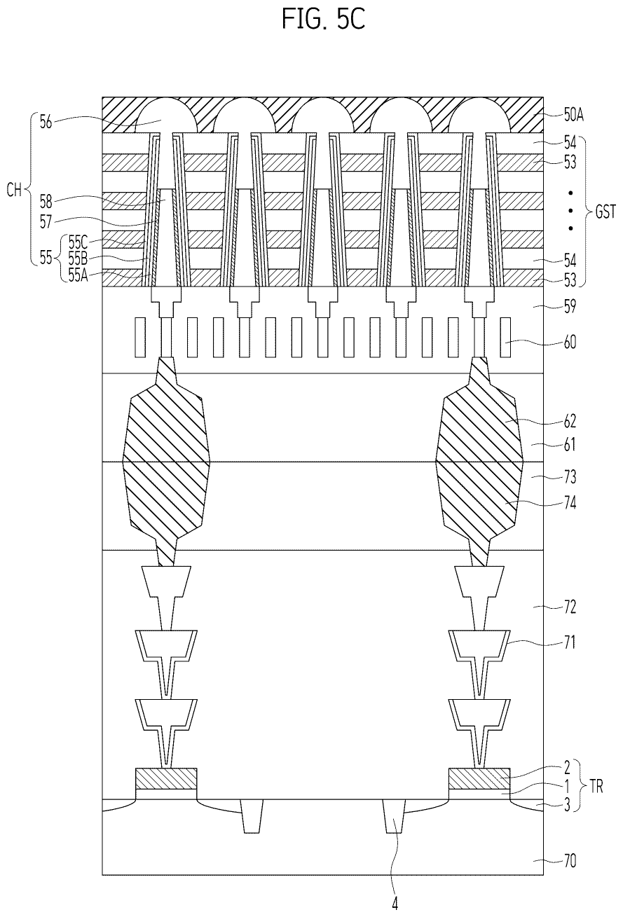

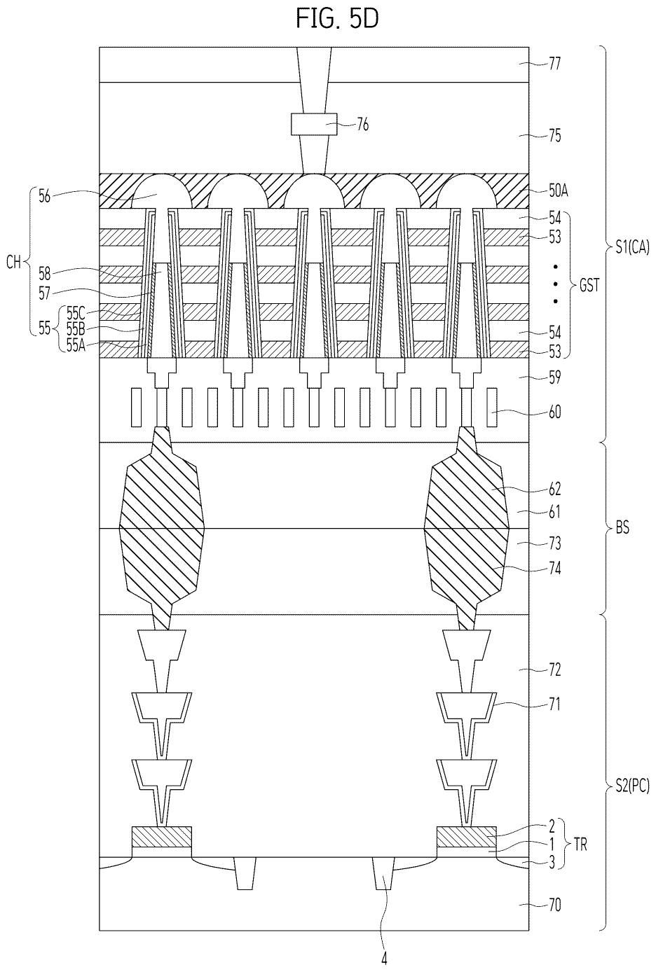

FIGS. 5A to 5D are diagrams for describing a method of manufacturing a semiconductor device in accordance with an embodiment. Hereinafter, content overlapping with the previously described content hereinabove may be omitted.

Referring to FIG. 5A, a first wafer W1 including a memory cell array CA may be formed. The first wafer W1 may include a substrate 50, a gate structure GST, a channel structure CH, an interlayer insulating layer 59, an interconnection structure 60, a bonding layer 61, and a bonding pad 62. The gate structure GST may include conductive layers 53 and insulating layers 54 that are alternately stacked. In the illustrated example of gate structure GST, one insulating layer 54 is located on the substrate 50, and one conductive layer 53 is located on the one insulating layer 54.

The channel structure CH may include a single crystal channel layer 56 or include a single crystal channel layer 56 and a polycrystalline channel layer 57. The single crystal channel layer 56 may be a single crystal silicon layer grown from the substrate 50 by an epitaxial method. The single crystal channel layer 56 may include a penetration portion extending through the gate structure GST and an expansion portion located in the substrate 50. The channel structure CH may further include at least one of an insulating core 58 and a memory layer 55. The memory layer 55 may include at least one of a blocking layer 55A, a data storage layer 55B, and a tunneling layer 55C.

Referring to FIG. 5B, a second wafer W2 including a peripheral circuit PC may be formed. The second wafer W2 may include a substrate 70, an element isolation layer 4, a transistor TR, an interlayer insulating layer 71, an interconnection structure 72, a bonding layer 73, and a bonding pad 74. The element isolation layer 4 may be located in the substrate 70, and an active region may be defined by the element isolation layer 4. The transistor TR may be located in the active region of the substrate 70 and may include a gate insulating layer 1, a gate electrode 2, and a junction 3.

Referring to FIG. 5C, the first wafer W1 and the second wafer W2 may be bonded to each other. The first wafer W1 may be turned over so that the substrate 50 is located on the gate structure GST and be bonded to the second wafer W2. The bonding layer 61 of the first wafer W1 and the bonding layer 73 of the second wafer W2 may be bonded to each other. The bonding pad 62 of the first wafer W1 and the bonding pad 74 of the second wafer W2 may be electrically connected to each other.

Subsequently, the substrate 50 may be etched, and a source layer 50A may be formed by doping the etched substrate 50 with impurities. When the substrate 50 is etched, the single crystal channel layer 56 may be partially etched. When the substrate 50 is doped with the impurities, the expansion portion of the single crystal channel layer 56 may also be doped with the impurities.

Referring to FIG. 5D, an interconnection structure 76, an interlayer insulating layer 75, and a passivation layer 77 may be formed on the source layer 50A. The interconnection structure 76 may be located in the interlayer insulating layer 75 and/or the passivation layer 77, and may be electrically connected to the source layer 50A or the like. Through this, a semiconductor device including a first semiconductor structure S1 including the memory cell array CA, a second semiconductor structure S2 including the peripheral circuit PC, and a bonding structure BS bonding the first semiconductor structure S1 and the second semiconductor structure S2 to each other may be manufactured.

According to the method described above, the first wafer W1 and the second wafer W2 may be formed, respectively, and then bonded to each other. After the first wafer W1 and the second wafer W2 are bonded to each other, the source layer 50A may be formed by doping the substrate 50 with the impurities. Accordingly, the source layer 50A may be formed using the substrate 50 without the need to remove the substrate 50 or deposit an additional conductive layer.

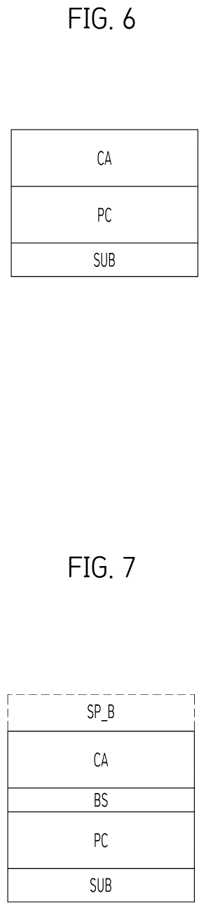

The structure and the manufacturing method according to the above-described embodiments may be applied to semiconductor devices of various structures. FIGS. 6 and 7 illustrate a schematic configuration of a semiconductor device to which the above-described embodiments are applicable.

FIG. 6 is a configuration diagram of a semiconductor device according to an embodiment of the present disclosure.

Referring to FIG. 6, the semiconductor device may include a substrate SUB, a peripheral circuit PC, and a memory cell array CA. In some embodiments, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. The group IV semiconductor may include single crystal silicon Si, polycrystalline silicon, germanium Ge, or silicon germanium SiGe. The group III-V compound semiconductor may include gallium arsenide (GaAs), gallium nitride (GaN), gallium phosphide (GaP), gallium arsenide phosphide (GaAsP), gallium indium arsenide phosphide (GaInAsP), aluminum arsenide (AlAs), aluminum-gallium (AlGa), indium phosphide (InP), indium antimonide (InSb), or indium gallium arsenide (InGaAs). The group II-VI compound semiconductor may include zinc sulfide (ZnS), zinc oxide (ZnO), or cadmium sulfide (CdS).

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 7 is a configuration diagram of a semiconductor device according to an embodiment of the present disclosure.

Referring to FIG. 7, the semiconductor device may include a substrate SUB, a peripheral circuit PC, a bonding structure BS, and a memory cell array CA. In some embodiments, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

In an alternate embodiment, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like, formed on different wafers, may be electrically connected without a separate bonding pad.

Other configurations of the semiconductor device may be implemented, equal to or in a similar manner to those described above with reference to FIG. 6.

Meanwhile, the semiconductor device may have a structure in which the embodiments described above with reference to FIGS. 6 and 7 are combined or may have a partially modified structure. In the embodiment described with reference to FIGS. 6 and 7, positions of the memory cell array CA and the peripheral circuit PC may be changed. At least one memory cell array CA and/or at least one peripheral circuit PC may be additionally bonded to the embodiment described with reference to FIGS. 6 and 7. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including conductive layers and insulating layers that are alternately stacked;
a single crystal channel layer; and
a source layer,
wherein the single crystal channel layer includes
a penetration portion extending through the gate structure, and
an expansion portion protruding from the gate structure and having a greater width than the penetration portion at a portion where the penetration portion and the expansion portion are connected, and
wherein the source layer is located above the gate structure and surrounds the expansion portion.

2. The semiconductor device of claim 1, wherein the expansion portion has a hemispherical shape.

3. The semiconductor device of claim 1, wherein the expansion portion is in contact with an upper surface of the gate structure, and includes a curved surface protruding from the upper surface of the gate structure.

4. The semiconductor device of claim 1, further comprising a memory layer surrounding a sidewall of the penetration portion.

5. The semiconductor device of claim 1, further comprising a polycrystalline channel layer extending through the gate structure and connected to the single crystal channel layer.

6. The semiconductor device of claim 5, further comprising an insulating core located in the polycrystalline channel layer.

7. The semiconductor device of claim 5, further comprising a memory layer surrounding the penetration portion and the polycrystalline channel layer.

8. The semiconductor device of claim 1,
wherein the gate structure, the single crystal channel layer, and the source layer form a cell array, and
wherein the semiconductor device further includes:
a peripheral circuit;
a first bonding pad electrically connected to the cell array; and
a second bonding pad bonded to the first bonding pad and electrically connected to the peripheral circuit.

9. A method of manufacturing a semiconductor device, the method comprising:
forming a first opening in a substrate;
forming a stack on the substrate;
forming a second opening extending through the stack and connected to the first opening;
forming a single crystal channel layer in the first opening and the second opening;
etching the substrate; and
forming a source layer by doping the etched substrate with impurities.

10. The method of claim 9, wherein the first opening includes a portion having a greater width than the second opening at a portion where the first opening and the second opening are connected.

11. The method of claim 9, wherein the forming of the first opening comprises:
forming an initial opening in the substrate; and
forming the first opening by expanding the initial opening.

12. The method of claim 9, further comprising performing a cleaning process on the substrate with the first opening.

13. The method of claim 9, further comprising doping the substrate with the impurities through the first opening.

14. The method of claim 9, further comprising:
forming a protective layer in the first opening; and
forming an etch-stop layer on the protective layer.

15. The method of claim 14, wherein the protective layer includes oxide, and the etch-stop layer includes carbon.

16. The method of claim 14, further comprising:
removing the etch-stop layer through the second opening; and
removing the protective layer.

17. The method of claim 9, further comprising forming a memory layer on an inner wall of the second opening.

18. The method of claim 9, wherein the forming of the single crystal channel layer comprises growing single crystal silicon from the substrate exposed through the first opening using an epitaxial growth method.

19. The method of claim 9, further comprising forming a polycrystalline channel layer in the second opening, the polycrystalline channel layer being connected to the single crystal channel layer.

20. The method of claim 19, further comprising forming an insulating core in the polycrystalline channel layer.

21. The method of claim 9, further comprising bonding a first wafer and a second wafer to each other, the first wafer including the substrate, the stack, and the single crystal channel layer, and the second wafer including a peripheral circuit.

22. The method of claim 9, further comprising forming a buffer layer by oxidizing the substrate,
wherein the etched substrate are doped with the impurities through the buffer layer.

23. A method of manufacturing a semiconductor device, the method comprising:
forming a first wafer including a substrate, a stack formed on the substrate, and a single crystal channel layer extending into the substrate through the stack;
forming a second wafer including a peripheral circuit;
bonding the first wafer and the second wafer to each other;
etching the substrate; and
forming a source layer by doping the etched substrate with impurities.

24. The method of claim 23, wherein the forming of the first wafer comprises:
forming a first opening in the substrate;
forming the stack on the substrate;
forming a second opening extending through the stack and connected to the first opening; and
forming the single crystal channel layer in the first opening and the second opening.

25. The method of claim 24, wherein the forming of the single crystal channel layer comprises growing a single crystal silicon layer from the substrate exposed through the first opening.

26. The method of claim 24, further comprising forming a polycrystalline channel layer in the second opening, the polycrystalline channel layer being connected to the single crystal channel layer.

27. The method of claim 23, further comprising a buffer layer by oxidizing a surface of the etched substrate,
wherein the etched substrate is doped with the impurities through the buffer layer.
